(19) United States
(12) Patent Application Publication
(10) Pub. No.: US 2026/0162610 A1
(43) Pub. Date: Jun. 11, 2026

(54) PIXEL CIRCUIT AND DISPLAY DEVICE INCLUDING THE SAME

(71) Applicant: LG DISPLAY CO., LTD., Seoul (KR)

(72) Inventors: Dong Kyu KIM, Paju-si (KR); Guen Sik LEE, Paju-si (KR)

(73) Assignee: LG DISPLAY CO., LTD., Seoul (KR)

(21) Appl. No.: 19/341,441

(22) Filed: Sep. 26, 2025

(30) Foreign Application Priority Data
Dec. 5, 2024 (KR) 10-2024-0179039

(51) Int. Cl. G09G 3/3233; G02F 1/29; H10K 59/50

(52) U.S. Cl. CPC G09G 3/3233; G02F 1/29; H10K 59/50; G09G 2300/0421; G09G 2300/0814; G09G 2300/0819; G09G 2300/0852; G09G 2300/0861; G09G 2310/08; G09G 2320/045; G09G 2320/068; G09G 2380/10

(57) ABSTRACT

A pixel circuit according to one or more examples includes: a light-emitting element; a driving element configured to drive the light-emitting element; a compensation circuit including a first capacitor, the first capacitor including a first electrode to which a first data voltage is applied via a data line and a second electrode connected to a gate electrode of the driving element; a first switch element to which a predetermined second data voltage is supplied via the data line; and a second capacitor including a first electrode connected to a second electrode of the first switch element and a second electrode connected to a power line to which a common voltage is applied. A display device including the pixel circuit is also disclosed.

### CROSS-REFERENCE TO RELATED APPLICATIONS

This application claims the benefit of and priority to Korean Patent Application No. 10-2024-0179039, filed Dec. 5, 2024, the entire contents of which are incorporated herein by reference for all purposes.

### BACKGROUND

### 1. Technical Field

The present disclosure relates to a pixel circuit and a display device including the same.

### 2. Description of Related Art

Variable viewing angle technology is being applied to display devices. Variable viewing angle technology may present video content or visual information reproduced on a display device only to a user within a narrow viewing angle range, or to multiple users within a wide viewing angle range.

As the market for future vehicles such as electric vehicles and self-driving cars expands, demand for vehicle display devices is rapidly increasing. Research is being conducted on a method of dividing the screen of a vehicle display device and controlling one part of the screen to have a narrow viewing angle and the other part to have a wide viewing angle. This technology may drive pixels with a narrow viewing angle arranged in one area of the screen to display personal contents or information that only a specific user may view, and simultaneously drive pixels with a wide viewing angle arranged in the other area of the screen to display shared contents that multiple users may view together.

In vehicle display devices, display panels for organic light emitting display devices are attracting attention. An organic light emitting display device includes an organic light emitting diode (hereinafter, referred to as “OLED”) that emits light by itself, and has an advantage in that the response speed is fast, the luminous efficiency and luminance are good, and the viewing angle is wide. The organic light emitting display device has a fast response speed, is excellent in terms of luminous efficiency, luminance and viewing angle, and provides an excellent contrast ratio and color reproducibility since it may express the black grayscale in complete black. Because the display panel of an organic light emitting display device may be flexibly bent, it may easily implement a curved surface. Due to these advantages, the share of organic light emitting display devices in the vehicle display device market is rapidly increasing.

The description of related art should not be considered prior art merely because it is mentioned in or associated with this section. The description of related art includes information that describes one or more aspects of the subject technology, and the description in this section does not limit the scope of the invention.

### SUMMARY

Each of pixels that are applied to a vehicular display device includes two lenses having different light viewing angles and two light-emitting elements. Since the two light-emitting elements are connected to one transistor, the size of the light-emitting element is reduced, and as a result, the lifetime of the light-emitting element is also reduced.

One or more aspects of the present disclosure are directed to solving all the above-described necessity and problems.

One or more aspects of the present disclosure provide a pixel circuit capable of adjusting a light viewing angle using one light-emitting element and a display device using the same.

It should be noted that aspects of the present disclosure are not limited to the above-described aspects, and other aspects of the present disclosure will be apparent to those skilled in the art from the following descriptions.

A pixel circuit according to embodiments of the present disclosure may include a light-emitting element; a driving element configured to drive the light-emitting element; a compensation circuit including a first capacitor, the first capacitor including a first electrode to which a first data voltage is applied via a data line and a second electrode connected to a gate electrode of the driving element; a first switch element to which a predetermined second data voltage is supplied via the data line; and a second capacitor including a first electrode connected to a second electrode of the first switch element and a second electrode connected to a power line to which a common voltage is applied.

A display device according to embodiments of the present disclosure may include a display panel including a display area in which a plurality of sub-pixels are provided, wherein the display panel includes: a substrate; a circuit layer provided above the substrate; a light-emitting element layer provided above the circuit layer; an encapsulation layer provided above the light-emitting element layer; and a liquid crystal lens layer including a first electrode including multiple electrode patterns spaced apart from each other above the encapsulation layer, a liquid crystal layer that covers the first electrode, and a second electrode provided above the liquid crystal layer, and wherein a predetermined data voltage is applied to each of the multiple electrode patterns provided in the first electrode, and a predetermined common voltage is applied to the second electrode.

According to the embodiments of the present disclosure, one light-emitting element is provided for every pixel, the liquid crystal lens layer is formed above the light-emitting element layer in which the light-emitting element is provided, and the data voltage is selectively applied to the liquid crystal lens layer. Therefore, it is possible to adjust a light viewing angle using one light-emitting element without using two lenses and two light-emitting elements.

According to the embodiments of the present disclosure, since one light-emitting element is used for every pixel, it is not necessary to reduce the size of the light-emitting element, and as a result, it is possible to extend the lifetime of the light-emitting element.

According to the embodiments of the present disclosure, it is possible to implement the liquid crystal lens layer in various forms by pixel or by area.

According to the embodiments of the present disclosure, the lifetime of the light-emitting element is improved, and as a result, it is possible to achieve low power driving.

The effects of the present specification are not limited to the above-mentioned effects, and other effects that are not mentioned will be apparently understood by those skilled in the art from the following description and the appended claims.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a block diagram illustrating a display device according to an embodiment of the present disclosure;

FIG. 2 is a diagram illustrating a pixel circuit according to the embodiment of the present disclosure;

FIGS. 3A and 3B are diagrams illustrating mode-specific driving waveforms of the pixel circuit illustrated in FIG. 2;

FIGS. 4A to 4D are diagrams illustrating an operation principle of the pixel circuit according to FIG. 3B;

FIG. 5 is a diagram illustrating a cross section of a pixel in the display panel illustrated in FIG. 1;

FIGS. 6A and 6B are diagrams illustrating a shape of a first electrode illustrated in FIG. 5;

FIGS. 7A to 7C are diagrams illustrating a liquid crystal lens layer illustrated in FIG. 5;

FIG. 8 is a diagram illustrating a principle in which a light viewing angle is adjusted in units of pixels;

FIGS. 9A and 9B are diagrams illustrating an electrode pattern form formed by sub-pixel;

FIGS. 10A and 10B are diagrams illustrating a different shape of a first electrode illustrated in FIG. 5;

FIG. 11 is a diagram illustrating a principle in which a light viewing angle is adjusted in terms of areas;

FIGS. 12A to 12D are diagrams illustrating a mode switching principle according to the embodiment of the present disclosure;

FIG. 13 is a diagram illustrating a pixel circuit according to a second embodiment of the present disclosure;

FIGS. 14A and 14B are diagrams illustrating mode-specific driving waveforms of the pixel circuit illustrated in FIG. 13; and

FIGS. 15A to 15D are diagrams illustrating an operation principle of the pixel circuit according to FIG. 14B.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present specification and methods of achieving them will become apparent with reference to preferable embodiments, which are described in detail, in conjunction with the accompanying drawings. However, the present specification is not limited to the embodiments to be described below and may be implemented in different forms, the embodiments are only provided to completely disclose the present disclosure and completely convey the scope of the present disclosure to those skilled in the art, and the present specification is defined by the disclosed claims.

Since the shapes, sizes, proportions, angles, numbers, and the like disclosed in the drawings for describing the embodiments of the present disclosure are only examples, the present disclosure is not limited to the illustrated items. The same reference numerals indicate the same components throughout the specification. Further, in describing the present disclosure, when it is determined that a detailed description of related known technology may unnecessarily obscure the gist of the present disclosure, the detailed description thereof will be omitted.

When ‘including,’ ‘having,’ ‘consisting,’ and the like mentioned in the present specification are used, other parts may be added unless ‘only’ is used. A case in which a component is expressed in a singular form includes a plural form unless explicitly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to,’ and the like, one or more other parts may be located between the two parts unless ‘immediately’ or ‘directly’ is used.

Although first, second, and the like are used to describe various components, these components are not limited by these terms. These terms are only used to distinguish one component from another. Accordingly, a first component, which is mentioned, below may also be a second component within the technical spirit of the present disclosure.

The same reference numerals may refer to substantially the same elements throughout the present disclosure.

The following embodiments can be partially or entirely bonded to or combined with each other and can be linked and operated in technically various ways. The embodiments can be carried out independently of or in association with each other.

Hereinafter, various embodiments of the present disclosure will be described in detail with reference to the accompanying drawings.

In a display device of the present disclosure, the pixel circuit and the gate driving circuit may include a plurality of transistors. Transistors may be implemented as oxide thin film transistors (oxide TFTs) including an oxide semiconductor, low temperature polysilicon (LTPS) TFTs including low temperature polysilicon, or the like.

A transistor is a three-electrode element including a gate, a source, and a drain. The source is an electrode that supplies carriers to the transistor. In the transistor, carriers start to flow from the source. The drain is an electrode through which carriers exit from the transistor. In a transistor, carriers flow from a source to a drain. In the case of an n-channel transistor, since carriers are electrons, a source voltage is a voltage lower than a drain voltage such that electrons may flow from a source to a drain. The n-channel transistor has a direction of a current flowing from the drain to the source. In the case of a p-channel transistor (p-channel metal-oxide semiconductor (PMOS)), since carriers are holes, a source voltage is higher than a drain voltage such that holes may flow from a source to a drain. In the p-channel transistor, since holes flow from the source to the drain, a current flows from the source to the drain. It should be noted that a source and a drain of a transistor are not fixed. For example, a source and a drain may be changed according to an applied voltage. Therefore, the disclosure is not limited due to a source and a drain of a transistor. In the following description, a source and a drain of a transistor will be referred to as a first electrode and a second electrode.

A gate signal swings between a gate-on voltage and a gate-off voltage. The gate-on voltage is set to a voltage higher than a threshold voltage of a transistor, and the gate-off voltage is set to a voltage lower than the threshold voltage of the transistor.

The transistor is turned on in response to the gate-on voltage and is turned off in response to the gate-off voltage. In the case of the n-channel transistor, a gate-on voltage may be a gate high voltage, and a gate-off voltage may be a gate low voltage. In the case of the p-channel transistor, a gate-on voltage may be a gate low voltage, and a gate-off voltage may be a gate high voltage.

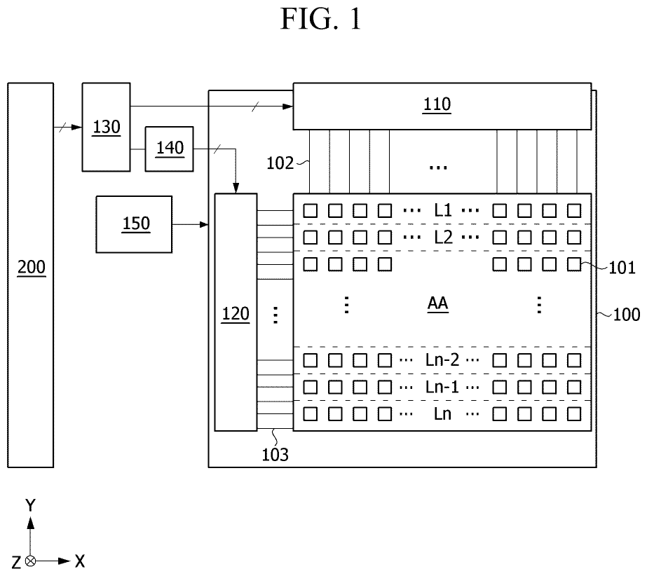

FIG. 1 is a block diagram illustrating a display device according to an embodiment of the present disclosure.

Referring to FIG. 1, the display device according to an embodiment of the present disclosure includes a display panel 100, and a display panel driving circuit for writing pixel data to pixels of the display panel 100. Additionally, the display device includes a power supply 150.

The display panel 100 may be, but not limited to, a panel having a rectangular structure with a length in the X-axis direction, a width in the Y-axis direction, and a thickness in the Z-axis direction. For example, the display panel 100 may be a heterogeneous panel of which at least a portion is curved or elliptical.

The display area AA of the display panel 100 includes a pixel array to display an input image. The pixel array includes a plurality of data lines 102, a plurality of gate lines 103 crossing the data lines 102, and pixels arranged in a matrix form. The display panel 100 may further include power lines commonly connected to the pixels. The power lines may be commonly connected to pixel circuits to supply a voltage required for driving pixels 101 to the pixels 101.

Each of the pixels 101 may be divided into a red sub-pixel, a green sub-pixel, and a blue sub-pixel for color implementation. Each pixel may further include a white sub-pixel. Each sub-pixel includes a pixel circuit for driving a light emitting element. The light emitting element may include an OLED or an inorganic light emitting diode (LED). Each pixel circuit is connected to the data lines, the gate lines, and the power lines. In the following description, a pixel may be interpreted as a sub-pixel.

The display area AA includes a plurality of pixel lines L1 to Ln. Each of the pixel lines L1 to Ln includes one line of pixels arranged along the line direction (X-axis direction) in the pixel array of the display panel 100. Those pixels arranged in one pixel line share the gate lines 103. The sub-pixels arranged in the column direction Y along the data line direction share the same data line 102. One horizontal period is a time obtained by dividing one frame period by the total number of pixel lines L1 to Ln.

The display panel 100 may be implemented with a non-transmissive display panel or a transmissive display panel. The transmissive display panel may be applied to a transparent display device in which an image is displayed on the screen and a real object in the background is visible. The display panel 100 may be made of a flexible display panel.

The power supply 150 receives an input voltage applied from the host system 200 and outputs a voltage needed to drive the pixels 101 of the display panel 100 and the display panel driving circuit. To this end, the power supply 150 may include a direct current to direct current converter (DC-DC converter). The DC-DC converter may include a charge pump, a regulator, a buck converter, a boost converter, and the like. The power supply 150 may output a constant voltage (or direct current voltage), such as gate-on voltage, gate-off voltage, pixel driving voltage, cathode voltage, reference voltage, IC driving voltage of the display panel driving circuit, through the DC-DC converter. The gate-on voltage and the gate-off voltage may be supplied to the level shifter 140 and the gate driver 120. Voltages such as pixel driving voltage, cathode voltage, and reference voltage may be supplied to the pixels 101 through the power lines commonly connected to the pixels 101.

The power supply 150 may further include a gamma voltage generator. The gamma voltage generator receives a high-potential reference voltage and a low-potential reference voltage and outputs a plurality of gamma reference voltages divided at specific intervals on a preset gamma curve, for example, a 2.2 gamma curve. The gamma reference voltages are supplied to the data driver 110. In the data driver 110, the gamma reference voltages are subdivided by a voltage dividing circuit into grayscale voltages. The gamma voltage generator may be implemented with a programmable gamma circuit that may adjust the voltage of each of the gamma reference voltages according to digital data. The timing controller 130, the host system 200, or a separate external device may update digital data stored in a register of the programmable gamma circuit through a communication interface.

The display panel driving circuit writes pixel data of the input image to the pixels 101 of the display panel 100 under the control of the timing controller 130. The display panel driving circuit includes a data driver 110 and a gate driver 120.

The display panel driving circuit may further include a touch sensor driver for driving touch sensors. The touch sensor driver is not shown in FIG. 1. The data driver 110 and the touch sensor driver may be integrated into one source drive IC.

The data driver 110 receives pixel data of the input image as a digital signal from the timing controller 130 and outputs a data voltage. The data driver 110 may receive gamma reference voltages and generate gamma compensation voltages for each grayscale through a voltage dividing circuit. The per-grayscale gamma compensation voltages are supplied to a digital to analog converter (hereinafter referred to as “DAC”) disposed in each channel of the data driver 110.

The data driver 110 samples and latches digital data received from the timing controller 130 and then inputs the digital data to the DAC. Here, the digital data includes pixel data of the input image. The DAC converts the pixel data into a gamma compensation voltage and outputs a data voltage of the pixel data.

The gate driver 120 may be formed on the display panel 100 together with the circuit elements and wiring lines of the display area AA. The gate driver 120 may be disposed in at least one of left and right non-display areas NA outside the display area AA in the display panel 100 or at least a part thereof may be disposed within the display area AA.

The gate driver 120 sequentially outputs pulses of the gate signals to the gate lines 103 under the control of the timing controller 130. The gate driver 120 may sequentially supply the gate signals to the gate lines 103 by shifting the pulses of the gate signals using shift registers. When a plurality of gate signals are applied to each pixel, the gate driver 120 may include a plurality of shift registers. The gate signal may include a scan signal being input to the pixel circuit through a plurality of gate lines, and an emission signal (or EM signal).

The gate driver 120 may be disposed in Gate In Panel (GIP) fashion in the non-display area, or in Gate in Active area (GIA) fashion between subpixels SP in the display area AA.

The timing controller 130 receives digital video data of an input image and a timing signal synchronized with this data from the host system 200. The timing signal may include a vertical synchronization signal Vsync, a horizontal synchronization signal Hsync, and a data enable signal DE. Since the vertical period and horizontal period may be known by counting the data enable signal DE, the vertical synchronization signal Vsync and the horizontal synchronization signal Hsync may be omitted. The horizontal synchronization signal Hsync and the data enable signal DE have a periodicity of 1 horizontal period (1H).

The timing controller 130 may control the display panel driving circuit by generating a data timing control signal for controlling the operation timing of the data driver 110 and a gate timing control signal for controlling the operation timing of the gate driver 120 based on the timing signals Vsync, Hsync, DE received from the host system 200. The timing controller 130 may synchronize the data driver 110 and the gate driver 120 by controlling the operation timing of the display panel driving circuit.

The gate timing control signal output from the timing controller 130 may be input to the shift register of the gate driver 120 through the level shifter 140. The level shifter 140 may convert a voltage of the gate timing control signal received from the timing controller 130 to a swing width between the gate-on voltage and the gate-off voltage and supply it to the gate driver 120.

The timing controller 130 may analyze the input image for each frame and generate a control signal for selectively outputting gate signals according to the analysis result. The generated control signal may be provided to the shift register of the gate driver 120 through the level shifter 140.

The host system 300 may include a main board of one of a television system, a set-top box, a navigation system, a personal computer (PC), a vehicle system, a mobile terminal, and a wearable terminal. The host system 300 may scale an image signal from a video source according to the resolution of the display panel 100, and may transmit it to the timing controller 130 together with the timing signals.

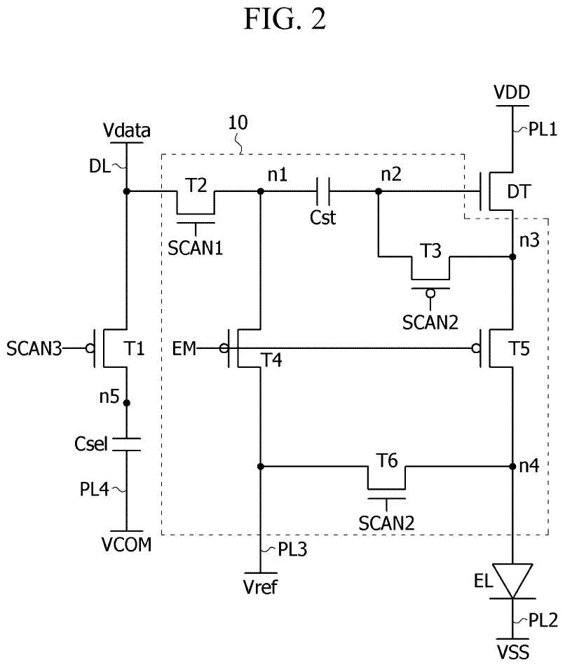

FIG. 2 is a diagram illustrating a pixel circuit according to the embodiment of the present disclosure.

Referring to FIG. 2, a pixel circuit according to a first embodiment of the present disclosure includes a light-emitting element EL, a driving element DT that drives the light-emitting element EL, a compensation circuit 10 including a first capacitor Cst, a switch element T1, and a second capacitor Csel. The compensation circuit 10 further includes a plurality of switch elements T2 to T6. The driving element DT and the plurality of switch elements T1 to T6 may be implemented by p-channel transistors, but the present disclosure is not limited thereto.

The driving element DT generates a current according to a gate-source voltage Vgs and drives the light-emitting element EL. The driving element DT includes a first electrode connected to a first power line PL1 to which a pixel driving voltage VDD is applied, a gate electrode connected to a second node n2, and a second electrode connected to a third node n3.

The light-emitting element EL may be implemented as organic light-emitting diodes (OLEDs). The light-emitting element EL includes an anode, a cathode, and an organic compound layer formed between the anode and the cathode. The anode of the light-emitting element EL is connected to a fourth node n4, and the cathode thereof is connected to the second power line PL2 to which the pixel base voltage VSS is applied. The organic compound layer may include a hole injection layer HIL, a hole transport layer HTL, an emission layer EML, an electron transport layer ETL, and an electron injection layer EIL, but the present disclosure is not limited thereto. The light-emitting element EL may be implemented in a tandem structure in which a plurality of light-emitting layers are stacked. The light-emitting element EL of the tandem structure may improve the luminance and lifetime of the pixel.

The first switch element T1 is connected between a fifth node n5 and a data line DL. The first switch element T1 is turned on according to a gate on voltage VGL of a third scan signal SCAN3 and connects the fifth node n5 to the data line DL to which a first data voltage Vdata1 is applied. The first switch element T1 includes a first electrode connected to the data line DL, a gate electrode to which the third scan signal SCAN3 is applied, and a second electrode connected to the fifth node n5.

The second switch element T2 is connected between the data line DL and a first node n1. The second switch element T2 is turned on a gate on voltage VGL of a first scan signal SCAN1 and applies a second data voltage Vdata2 of pixel data to the first node n1. The second switch element T2 includes a first electrode connected to the data line DL, a gate electrode to which the first scan signal SCAN1 is applied, and a second electrode connected to the first node n1.

The third switch element T3 is connected between the second node n2 and the third node n3. The third switch element T3 is turned on according to a gate on voltage VGL of a second scan signal SCAN2 and connects the gate electrode and the second electrode of the driving element DT. The third switch element T3 includes a first electrode connected to the second node n2, a gate electrode to which the second scan signal SCAN2 is applied, and a second electrode connected to the third node n3.

The fourth switch element T4 is connected between the first node n1 and a third power line PL3. The fourth switch element T4 is turned on according to a gate on voltage VGL of a light emission control signal EM and connects the first node n1 to the third power line PL3. The fourth switch element T4 includes a first electrode connected to the first node n1, a gate electrode to which the light emission control signal EM is applied, and a second electrode connected to the third power line PL3.

The fifth switch element T5 is connected between the third node n3 and a fourth node n4. The fifth switch element T5 is turned on the gate on voltage VGL of the light emission control signal EM and connects the third node n3 to the fourth node n4. The fifth switch element T5 includes a first electrode connected to the third node n3, a gate electrode to which the light emission control signal EM is applied, and a second electrode connected to the fourth node n4.

The sixth switch element T6 is connected between the fourth node n4 and the third power line PL3. The sixth switch element T6 is turned on according to the gate on voltage VGL of the second scan signal SCAN2 and connects the fourth node n4 to the third power line PL3 to which a reference voltage Vref is applied. The sixth switch element T6 includes a first electrode connected to the third power line PL3, a gate electrode to which the second scan signal SCAN2 is applied, and a second electrode connected to the fourth node n4.

The first capacitor Cst is connected between the first node n1 and the second node n2. The second capacitor Csel is connected between the fifth node n5 and a fourth power line PL4 to which a common voltage VCOM is applied.

When the second switch element T2 is turned on, the first data voltage Vdata1 applied via the data line DL may be charged in the first capacitor Cst, and when the first switch element T1 is turned on, the second data voltage Vdata2 may be charged in the second capacitor Csel.

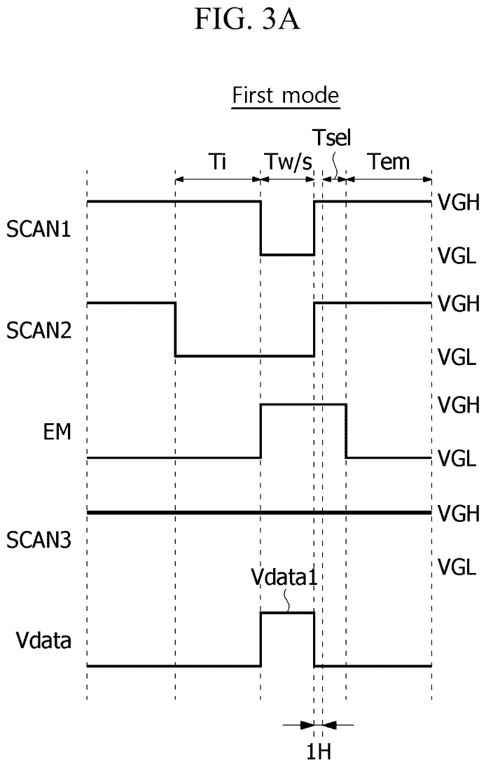

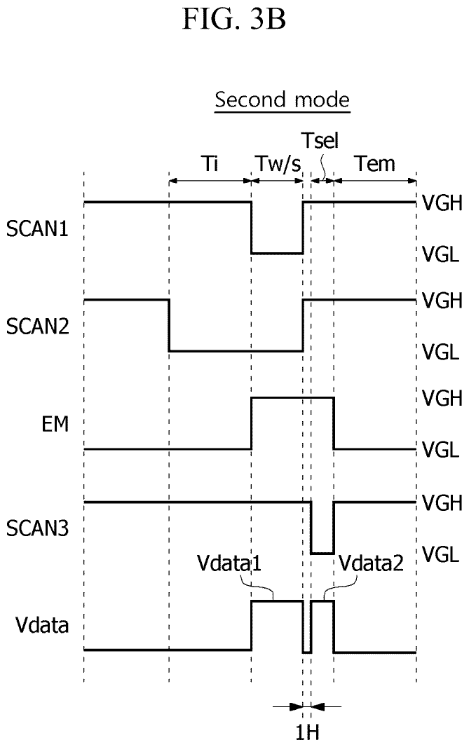

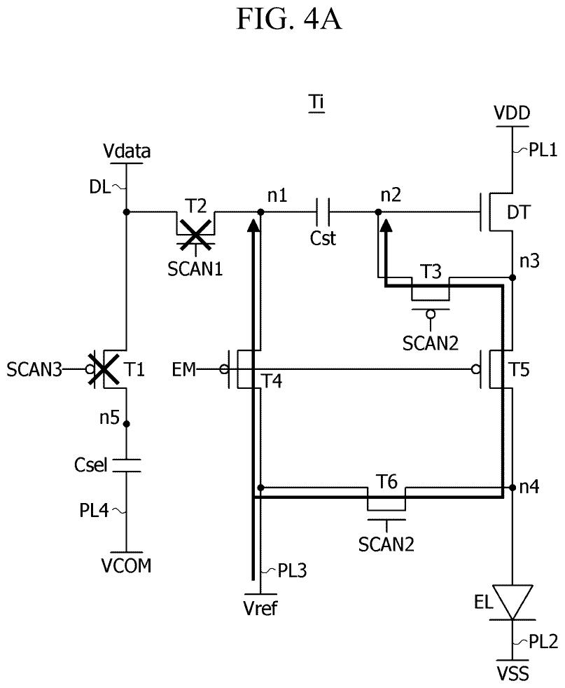

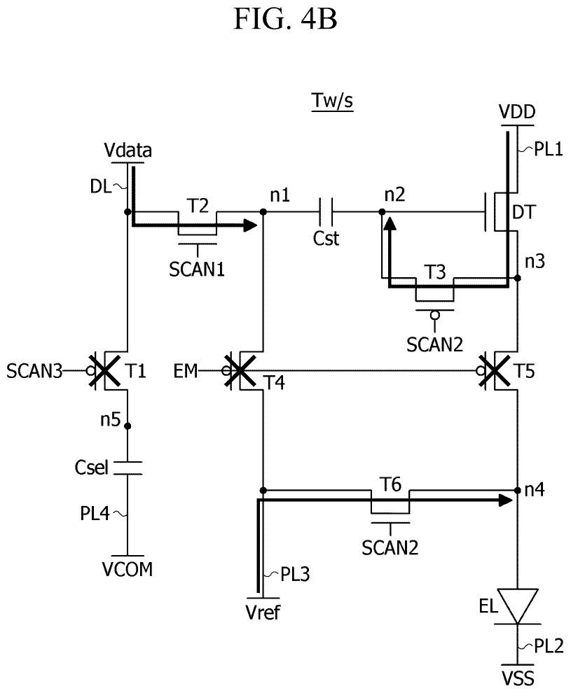

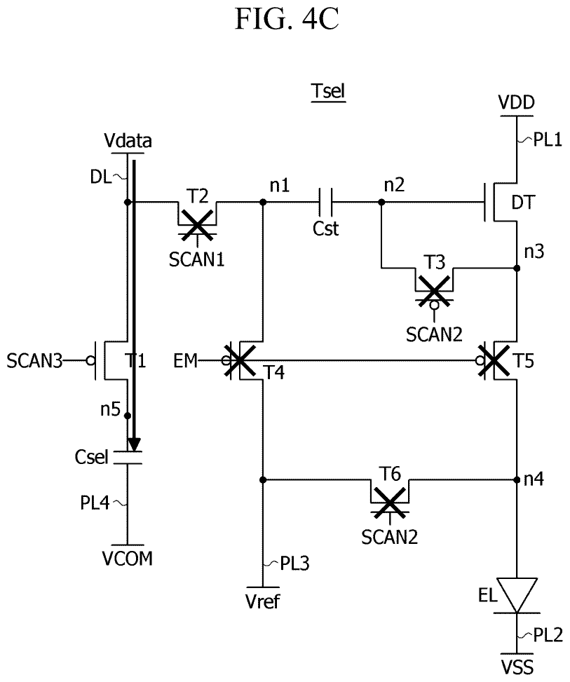

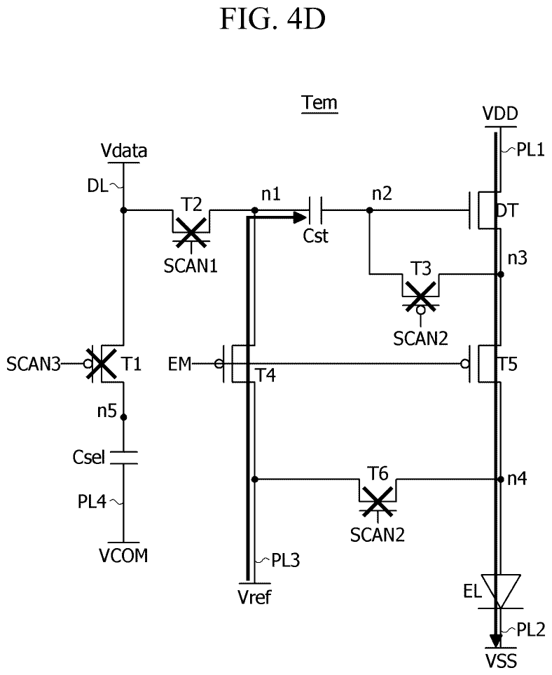

FIGS. 3A and 3B are diagrams illustrating mode-specific driving waveforms of the pixel circuit illustrated in FIG. 2 and FIGS. 4A to 4D are diagrams illustrating an operation principle of the pixel circuit according to FIG. 3B.

Referring to FIGS. 3A and 3B, the pixel circuit is driven in an order of an initialization period Ti, a data writing and sensing period Tw/s, a selection period Tsel, and a light emission period Tem in a first mode and a second mode.

In the first mode, light emitted from the light-emitting element may be emitted at a wide viewing angle, and in the second mode, light emitted from the light-emitting element may be emitted at a narrow viewing angle.

Referring to FIG. 4A, during the initialization period Ti, the first and second switch elements T1 and T2 are turned off, and the third to sixth switch elements T3 to T6 are turned on. Then, the reference voltage Vref is applied to the first node n1 and the second node n2.

Referring to FIG. 4B, during the data writing and sensing period Tw/s, the first switch element T1 and the fourth and fifth switch elements T4 and T5 are turned off, the second and third switch elements T2 and T3 and the sixth switch element T6 are turned on. Then, the first data voltage Vdata1 of the pixel data is applied to the first node n1, and the pixel driving voltage VDD is applied to the driving element. Accordingly, a threshold voltage Vth of the driving element is sensed, and as a result, a voltage of the second node n2 becomes VDD+Vth. Further, the reference voltage Vref is applied to the fourth node n4.

Referring to FIG. 4C, during the selection period Tsel, in the first mode, the first to sixth switch elements T1 to T6 are turned off, and in the second mode, the second to sixth switch elements T2 to T6 are turned off and the first switch element T1 is turned on. Then, the second data voltage Vdata2 is applied to the fifth node n5.

The data writing and sensing period Tw/s and the selection period Tsel are sections where different data voltages are applied. For this reason, to vary the data voltage, the selection period Tsel may start after at least 1 H from when the data writing and sensing period Tw/s ends.

Referring to FIG. 4D, during the light emission period Tem, the first to third switch elements T1 to T3 and the sixth switch element T6 are turned off, and the fourth and fifth switch elements T4 and T5 are turned on. Then, the current generated according to the gate-source voltage of the driving element DT is supplied to the light-emitting element EL and light is emitted from the light-emitting element EL. As a result, the voltage of the first node n1 becomes “Vref”, and the voltage of the second node n2 becomes “Vref−Vdata+VDD+Vth”.

During the light emission period Tem, in the first mode, since the second data voltage Vdata2 is not applied to the second capacitor Csel, the light viewing angle is maintained wide. In the second mode, the light viewing angle is narrowed due to the second data voltage Vdata2 and the common voltage VCOM applied to the second capacitor Csel.

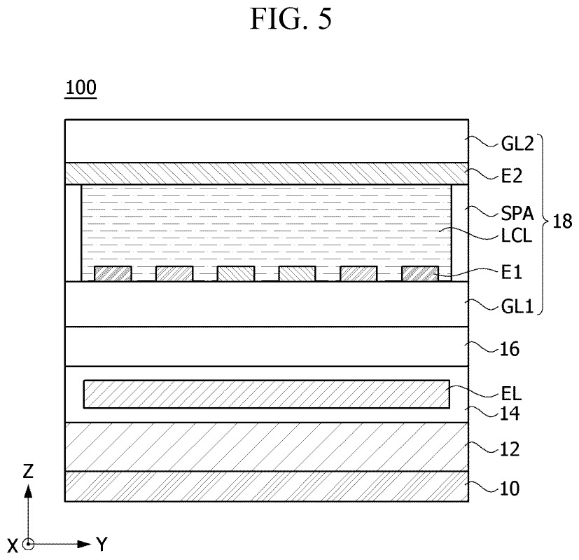

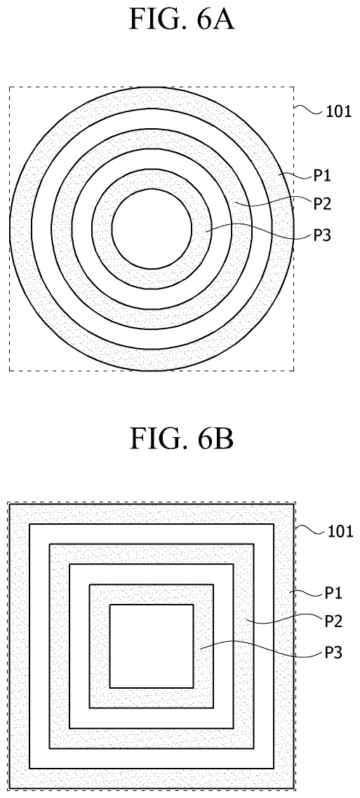

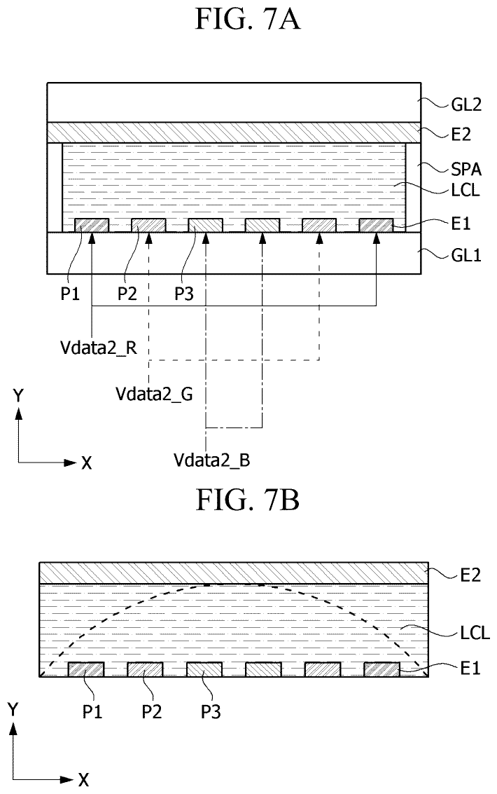

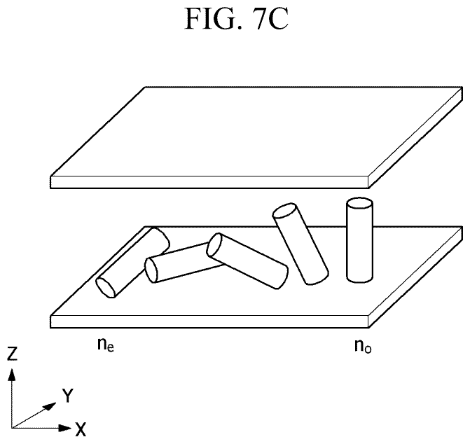

FIG. 5 is a diagram illustrating a cross section of a pixel in the display panel illustrated in FIG. 1, FIGS. 6A and 6B are diagrams illustrating a shape of a first electrode illustrated in FIG. 5 and FIGS. 7A to 7C are diagrams illustrating a liquid crystal lens layer illustrated in FIG. 5.

Referring to FIG. 5, a display panel 100 according to the embodiment of the present disclosure may include a substrate 10, a circuit layer 12, a light-emitting element layer 14, an encapsulation layer 16, and a liquid crystal lens layer 18.

The substrate 10 may be made of plastic with flexibility. For example, the substrate 10 may be manufactured as a single-layer or multilayer substrate made of a material selected from polyimide, polyethylene terephthalate, polyethylene naphthalate, polycarbonate, polyethersulfone, polyarylate, polysulfone, and cyclic-olefin copolymer, but the present disclosure is not limited thereto. For example, the substrate 10 may be a ceramic substrate or a glass substrate.

The circuit layer 12 may include a pixel circuit connected to wires such as a data line, a gate line, and power lines, a gate driver connected to the gate lines, a demultiplexer array and a circuit for an auto probe test (not illustrated), and the like. The wires and circuit elements of the circuit layer 12 may include a plurality of insulting layers, two or more metal layers separated with the insulating layer interposed between, and an active layer containing a semiconductor material. All transistors formed in the circuit layer 12 may be implemented by TFTs including an n-channel oxide semiconductor, but the present disclosure is not limited thereto.

The light-emitting element layer 14 may include the light-emitting element EL that is driven by the pixel circuit. The light-emitting element EL may include a red (R) light-emitting element, a green (G) light-emitting element, and a blue (B) light-emitting element. The light-emitting element layer 14 may include a white light-emitting element and a color filter. The light-emitting elements EL in the light-emitting element layer 14 may be covered with a protection layer including an organic film and a protection film.

The encapsulation layer 16 covers the light-emitting element layer 14 to encapsulate the circuit layer 12 and the light-emitting element layer 14. The encapsulation layer 16 may have a multi-insulating-film structure in which an organic film and an inorganic film are stacked alternately. The inorganic film blocks penetration of moisture or oxygen. The organic film planarizes the surface of the inorganic film. When the organic film and the inorganic film are stacked in various layers, a path of movement of moisture or oxygen is extended compared to a single layer, and as a result, the penetration of moisture and oxygen that affect the light-emitting element layer 14 can be effectively blocked.

The liquid crystal lens layer 18 may be formed on the encapsulation layer 16. The liquid crystal lens layer 18 serves to adjust a light viewing angle. The liquid crystal lens layer 18 includes a first glass layer GL1, a first electrode E1, a liquid crystal layer LCL, a second electrode E2, a second glass layer GL2, and spacers SPA.

The first glass layer GL1 may be provided above the encapsulation layer 16. The first electrode E1 may be provided above the first glass layer GL1, the liquid crystal layer LCL that covers the first electrode E1 may be provided, and the second electrode E2 may be provided above the liquid crystal layer LCL. The second glass layer GL2 may be provided above the second electrode E2.

The first electrode E1 includes multiple electrode patterns P1, P2, and P3, and the multiple electrode patterns P1, P2, and P3 are not electrically connected to each other. The multiple electrode patterns P1, P2, and P3 may have a circular ring shape as in FIG. 6A or may have a quadrangular ring shape as in FIG. 6B, but the present disclosure is not limited thereto.

The multiple electrode patterns P1, P2, and P3 may include a first electrode pattern P1, a second electrode pattern P2, and a third electrode pattern P3. The first electrode pattern P1 may be greater in size than the second electrode pattern P2, and the second electrode pattern P2 may be greater in size than the third electrode pattern P3. The first electrode pattern P1, the second electrode pattern P2, and the third electrode pattern P3 may have the same thickness D.

The second electrode pattern P2 may be provided inward the first electrode pattern P1 and spaced at a given distance L from the first electrode pattern P1, and the third electrode pattern P3 may be provided inward the second electrode pattern P2 and spaced at the given distance L from the second electrode pattern P2.

The second electrode E2 may be formed as one electrode in the display area unlike the first electrode.

The spacers SPA may separate the liquid crystal layer in units of pixels in which the light viewing angle is adjusted, but the present disclosure is not limited thereto. For example, the spacers SPA may separate the liquid crystal layer in units of areas.

The second data voltage may be applied to the first electrode E1, and the common voltage may be applied to the second electrode E2. As a result, a refractive index of a liquid crystal material in the liquid crystal layer may be made different, and the light viewing angle may be made different.

In the embodiment, different second data voltages are applied to the first to third electrode patterns P1, P2, and P3 of the first electrode such that the refractive index of the liquid crystal material is made different as in FIG. 7A. The level of the second data voltage that is applied to each of the first to third electrode patterns may be lowered from a central area toward an outside area of the pixel. A second data voltage Vdata2_R of a highest first level may be applied to the first electrode pattern P1 provided in the central area, a second data voltage Vdata2_G of a second level lower than the first level may be applied to the second electrode pattern P2, and a second data voltage Vdata2_B of a third level lower than the second level may be applied to the third electrode pattern P3 provided in the most outside area.

The common voltage is applied to the second electrode, and the second data voltage of a different level is applied to each of the first to third electrode patterns of the first electrode. Then, the refractive index of the liquid crystal material may be made different according to the area where each of the first to third electrode patterns is provided as indicated by a dotted line in FIG. 7B.

For example, the refractive index of a smallest magnitude is formed in the area where the first electrode pattern is provided, the refractive index of a medium magnitude is formed in the area where the second electrode pattern is provided, and the refractive index of a greatest magnitude is formed in the area where the third electrode pattern is provided.

In full detail, when the second data voltage is not applied to the first electrode E1 as in FIG. 7C, an electric field is not applied to the liquid crystal material of the liquid crystal layer LCL. For this reason, liquid crystal molecules in the liquid crystal material have a first axis direction horizontal to the first glass layer GL1, that is, an X-axis direction. As a result, light emitted from the light-emitting element is scattered and the light viewing angle is widened.

On the other hand, when a predetermined second data voltage is applied to the first electrode E1, an electric field is applied to the liquid crystal material of the liquid crystal layer LCL due to the second data voltage applied to the first electrode E1 and the common voltage applied to the second electrode E2. For this reason, the liquid crystal molecules in the liquid crystal material have a second axis direction vertical to the first glass layer GL1, that is, a Y-axis direction. As a result, light emitted from the light-emitting element maintains straightness and the light viewing angle is narrowed.

In this case, the direction of the liquid crystal molecules may be different according to the level of the second data voltage. That is, as the level of the second data voltage is greater, the liquid crystal molecules may be closer to the Y-axis direction.

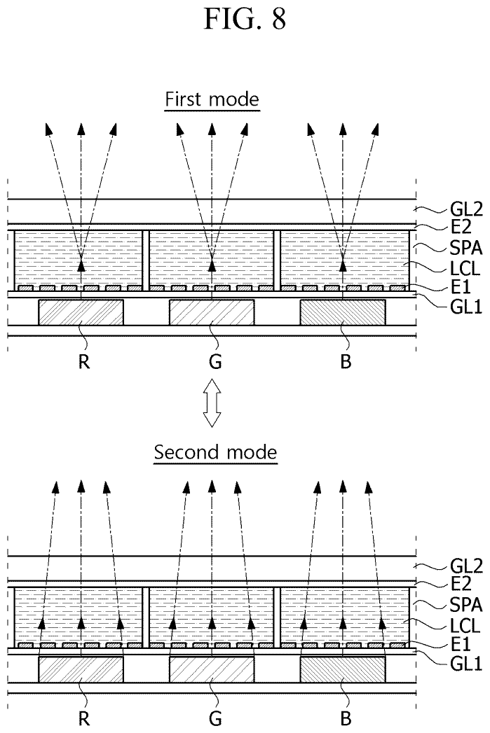

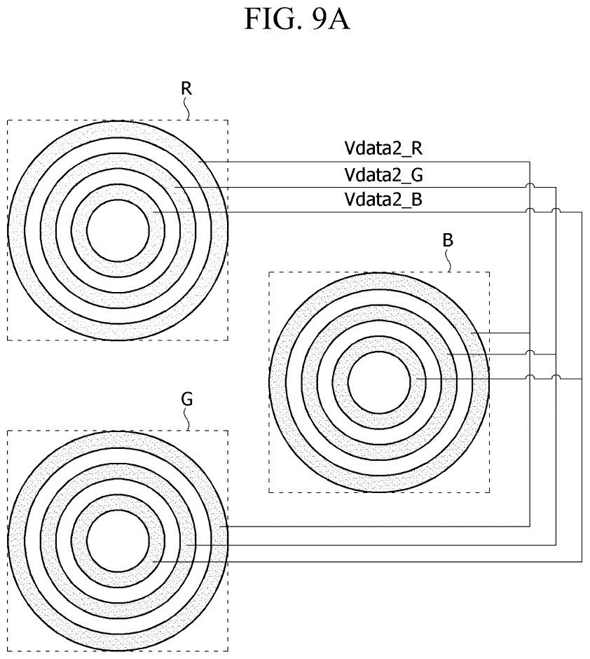

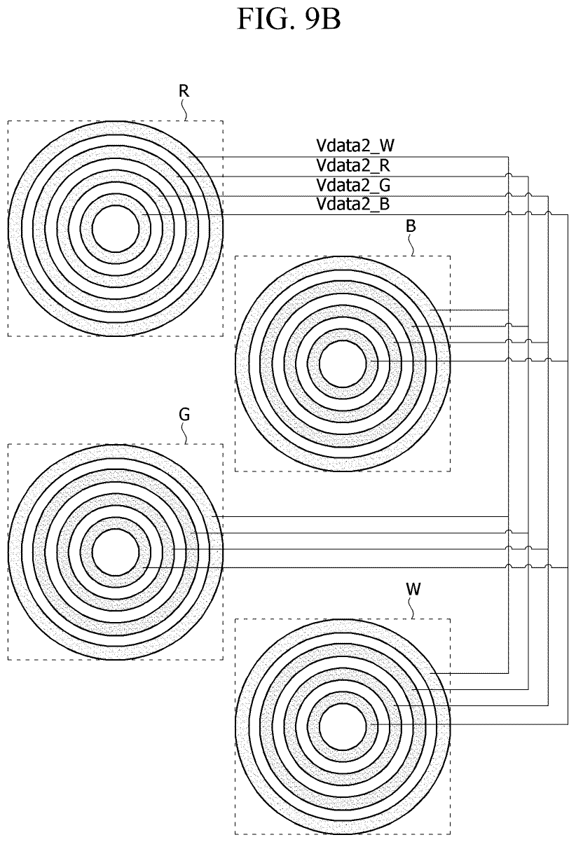

FIG. 8 is a diagram illustrating a principle in which a light viewing angle is adjusted in units of pixels and FIGS. 9A and 9B are diagrams illustrating an electrode pattern form formed by sub-pixel.

Referring to FIG. 8, multiple electrode patterns P1, P2, and P3 may be formed for each of the sub-pixel R, G, and B, and when the second data voltage is not applied to the multiple electrode patterns P1, P2, and P3, the light viewing angle may be formed wide.

On the other hand, when the second data voltage is applied to the multiple electrode patterns P1, P2, and P3, but different data voltages are applied to the multiple electrode patterns P1, P2, and P3 such that the areas have different refractive indexes as indicated by the dotted line, the light viewing angle may be formed narrowly.

In the embodiment, the first electrode may be provided by pixel. For example, as in FIG. 9A, the first electrode may be provided for each of a red sub-pixel R, a green sub-pixel G, and a blue sub-pixel B, and the light viewing angle may be adjusted in units of pixels.

The second data voltage Vdata2_R that is applied to the red sub-pixel R is applied in common to the first electrode patterns of the red sub-pixel R, the green sub-pixel G, and the blue sub-pixel B, the second data voltage Vdata_G that is applied to the green sub-pixel G is applied in common to the second electrode patterns, and the second data voltage Vdata_B that is applied to the blue sub-pixel B is applied in common to the third electrode patterns.

As another example, as in FIG. 9B, while a first electrode is provided for each of a red sub-pixel R, a green sub-pixel G, a blue sub-pixel B, and a white sub-pixel W, the first electrode includes fourth electrode patterns of a first electrode pattern P1, a second electrode pattern P2, a third electrode pattern P3, and a fourth electrode pattern P4, and the light viewing angle may be adjusted in units of pixels.

A second data voltage Vdata2_W that is applied to the white sub-pixel W is applied in common to the first electrode patterns P1 of the red sub-pixel R, the green sub-pixel G, the blue sub-pixel B, and the white sub-pixel W, a second data voltage Vdata2_R that is applied to the red sub-pixel R is applied in common to the second electrode patterns P2, a second data voltage Vdata_G that is applied to the green sub-pixel G is applied in common to the third electrode patterns P3, and a second data voltage Vdata_B that is applied to the blue sub-pixel B is applied in common to the fourth electrode patterns P4.

When each pixel includes the four sub-pixels as in FIG. 9B, the number of electrode patterns is large compared to a case where each pixel includes the three sub-pixels as in FIG. 9A, and the distribution of the refractive indexes may be formed gently. The electrode patterns described herein are merely an example, and the present disclosure is not limited thereto.

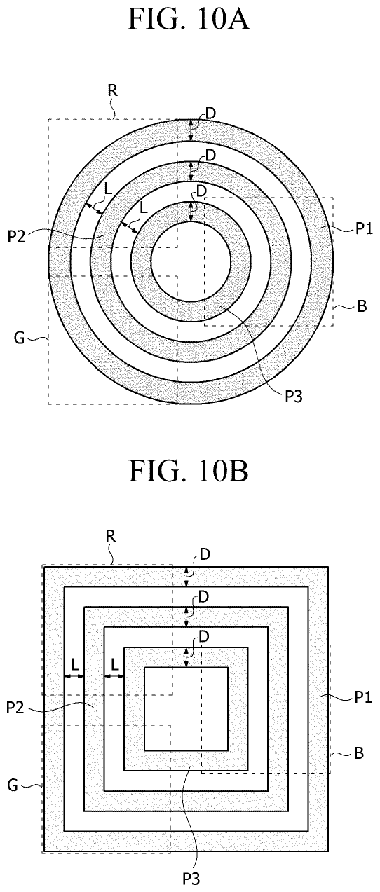

FIGS. 10A and 10B are diagrams illustrating a different shape of a first electrode illustrated in FIG. 5.

Referring to FIGS. 10A and 10B, multiple electrode patterns P1, P2, and P3 may be formed for every predetermined area where multiple sub-pixels R, G, and B are provided, and different second data voltages Vdata2_R, Vdata2_G, and Vdata2_B may be applied to the multiple electrode patterns P1, P2, and P3. Accordingly, the light viewing angle may be adjusted in units of areas.

The multiple electrode patterns P1, P2, and P3 may have a circular ring shape as in FIG. 9A or may have a quadrangular ring shape as in FIG. 9B, but the present disclosure is not limited thereto.

The first electrode pattern P1 may be greater in size than the second electrode pattern P2, and the second electrode pattern P2 may be greater in size than the third electrode pattern P3. The first electrode pattern P1, the second electrode pattern P2, and the third electrode pattern P3 may have the same thickness D.

The second electrode pattern P2 may be provided inward the first electrode pattern P1 and spaced at a given distance L from the first electrode pattern P1, and the third electrode pattern P3 may be provided inward the second electrode pattern P2 and spaced at the given distance L from the second electrode pattern P2.

Here, while an example where the three sub-pixels R, G, and B are set as one area has been described, the present disclosure is not limited thereto. For example, when the display area is divided into n areas, multiple electrode patterns P1, P2, and P3 may be formed for each of the n areas.

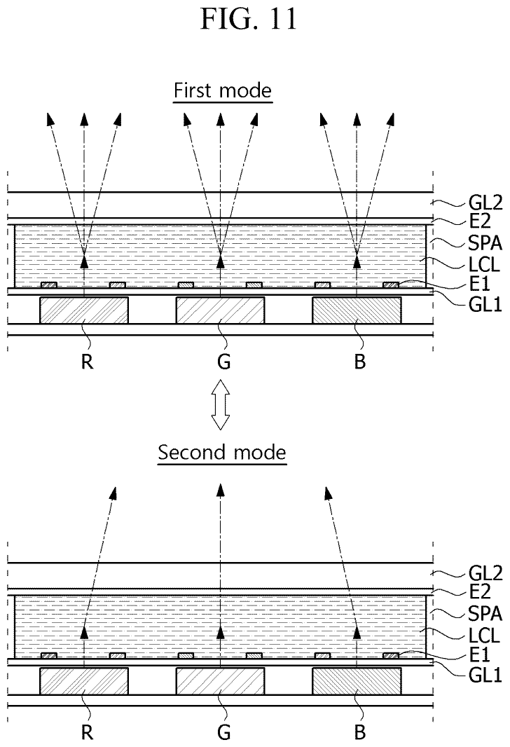

FIG. 11 is a diagram illustrating a principle in which a light viewing angle is adjusted in terms of areas.

Referring to FIG. 11, when multiple electrode patterns P1, P2, and P3 are formed for every predetermined area where multiple sub-pixels R, G, and B are provided, and a second data voltage is not applied to the multiple electrode patterns P1, P2, and P3, the light viewing angle may be formed wide.

On the other hand, when the second data voltage is applied to the multiple electrode patterns P1, P2, and P3, but different data voltages are applied to the multiple electrode patterns P1, P2, and P3 such as the areas have different refractive indexes as indicated by a dotted line, the light viewing angle may be formed narrowly.

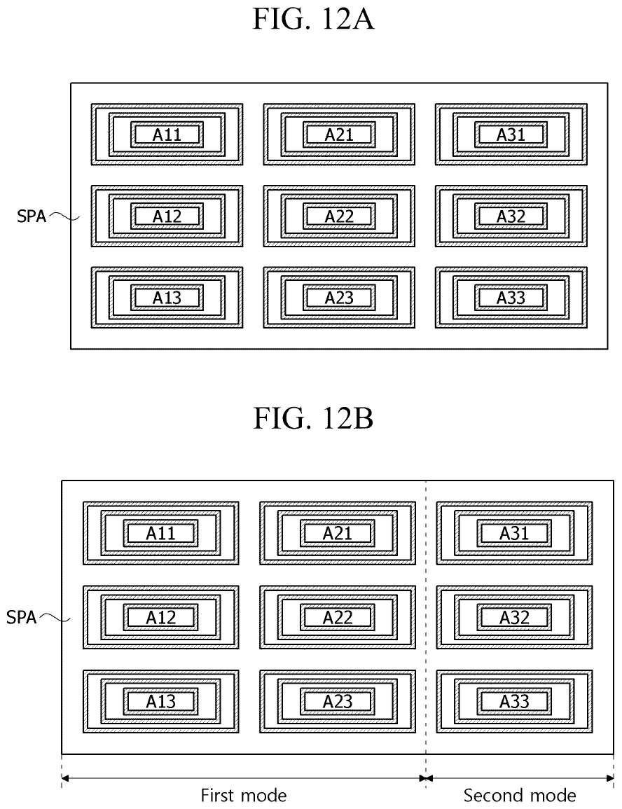

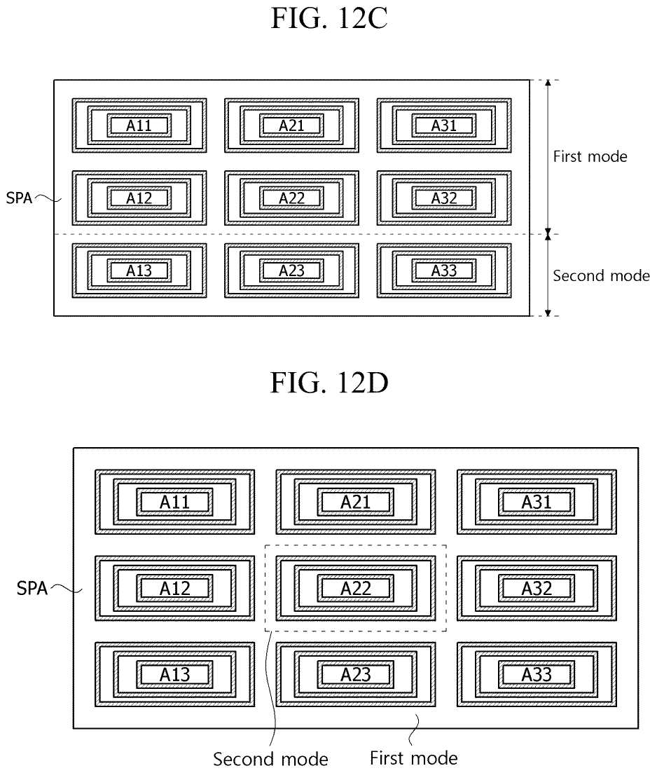

FIGS. 12A to 12D are diagrams illustrating a mode switching principle according to the embodiment of the present disclosure.

Referring to FIG. 12A, in the embodiment of the present disclosure, when the display area is divided into nine areas, multiple electrode patterns P1, P2, and P3 may be formed for each of the nine areas. Each of the nine areas divided in this manner may be driven in the first mode and the second mode.

As an example, the nine areas may be divided into two parts as in FIG. 12B, six areas A11, A12, A13, A21, A22, and A23 may be driven in the first mode, and remaining three areas A31, A32, and A33 may be driven in the second mode.

As another example, the nine areas may be divided into two parts as in FIG. 12C, six areas A11, A21, A31, A12, A22, and A32 may be driven in the first mode, and remaining three areas A13, A23, and A33 may be driven in the second mode.

As another example, the nine areas may be divided into two parts as in FIG. 12D, eight areas A11, A12, A13, A21, A23, A31, A32, and A33 may be driven in the first mode, and remaining one area A32 may be driven in the second mode.

The reason that driving in various forms can be achieved is because mode switching can be performed by pixel or area. The illustration described herein is merely an example, and the present disclosure is not limited thereto.

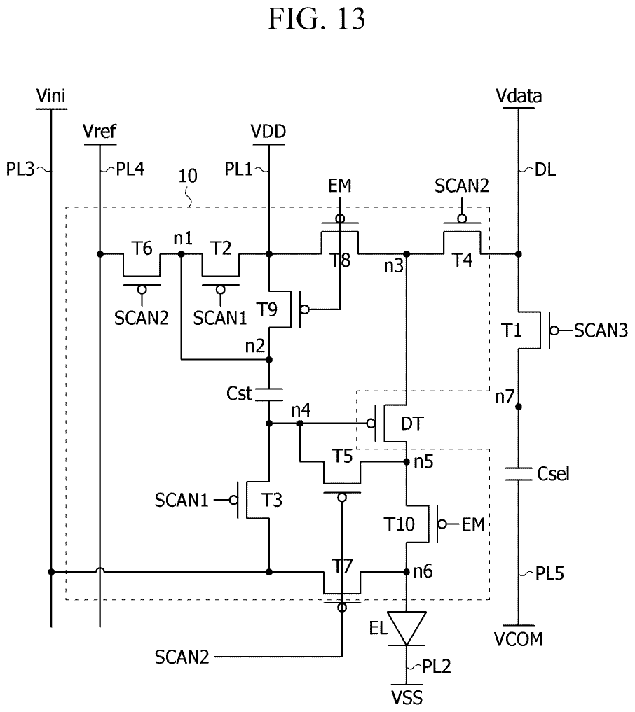

FIG. 13 is a diagram illustrating a pixel circuit according to a second embodiment of the present disclosure.

Referring to FIG. 13, a pixel circuit according to a second embodiment of the present disclosure includes a light-emitting element EL, a driving element DT that drives the light-emitting element EL, a compensation circuit 10 including a first capacitor Cst, a switch element T1, and a second capacitor Csel. The compensation circuit 10 further includes a plurality of switch elements T2 to T10. The driving element DT and the plurality of switch elements T1 to T9 may be implemented by p-channel transistors, but the present disclosure is not limited thereto.

The driving element DT generates a current according to a gate-source voltage Vgs and drives the light-emitting element EL. The driving element DT includes a first electrode connected to a third node n3, a gate electrode connected to a fourth node n4, and a second electrode connected to a fifth node n5.

The light-emitting element EL may be implemented as organic light-emitting diodes (OLEDs). The light-emitting element EL includes an anode, a cathode, and an organic compound layer formed between the anode and the cathode. The anode of the light-emitting element EL is connected to a fifth node n5, and the cathode thereof is connected to the second power line PL2 to which the pixel base voltage VSS is applied. The organic compound layer may include a hole injection layer HIL, a hole transport layer HTL, an emission layer EML, an electron transport layer ETL, and an electron injection layer EIL, but the present disclosure is not limited thereto. The light-emitting element EL may be implemented in a tandem structure in which a plurality of light-emitting layers are stacked. The light-emitting element EL of the tandem structure may improve the luminance and lifetime of the pixel.

The first switch element T1 is connected between a data line DL and a seventh node n7. The first switch element T1 is turned on according to a gate on voltage VGL of a third scan signal SCAN3 and applies a data voltage Vdata to the seventh node n7. The first switch element T1 includes a first electrode connected to the data line DL, a gate electrode to which the third scan signal SCAN3 or a mode selection signal is applied, and a second electrode connected to the seventh node n7.

The second switch element T2 is connected between a first power line PL1 and a first node n1. The second switch element T2 is turned on according to a gate on voltage VGL of a first scan signal SCAN1 and applies a pixel driving voltage VDD to the first node n1. The second switch element T2 includes a first electrode connected to the first node n1, a gate electrode to which the first scan signal SCAN1 is applied, and a second electrode connected to the first power line PL1 to which the pixel driving voltage VDD is applied.

The third switch element T3 is connected between a third power line PL3 and the fourth node n4. The third switch element T3 is turned on according to the gate on voltage VGL of the first scan signal SCAN1 and applies an initialization voltage Vini to the fourth node n4. The third switch element T3 includes a first electrode connected to the fourth node n4, a gate electrode to which the first scan signal SCAN1 is applied, and a second electrode connected to the third power line PL3 to which the initialization voltage Vini is applied.

The fourth switch element T4 is connected between the data line DL and the third node n3. The fourth switch element T4 is turned on according to a gate on voltage VGL of a second scan signal SCAN2 and applies a data voltage Vdata to the third node n3. The fourth switch element T4 includes a first electrode connected to the third node n3, a gate electrode to which the second scan signal SCAN2 is applied, and a second electrode connected to the data line DL to which the data voltage Vdata is applied.

The fifth switch element T5 is connected between the fourth node n4 and the fifth node n5. The fifth switch element T5 is turned on according to the gate on voltage VGL of the second scan signal SCAN2 and connects the gate electrode and the second electrode of the driving element DT. The fifth switch element T5 includes a first electrode connected to the fourth node n4, a gate electrode to which the second scan signal SCAN2 is applied, and a second electrode connected to the fifth node n5.

The sixth switch element T6 is connected between a fourth power line PL4 and the first node n1. The sixth switch element T6 is turned on according to the gate on voltage VGL of the second scan signal SCAN2 and applies a reference voltage Vref to the first node n1. The sixth switch element T6 includes a first electrode connected to the fourth power line PL4 to which the reference voltage Vref is applied, a gate electrode to which the second scan signal SCAN2 is applied, and a second electrode connected to the first node n1.

The seventh switch element T7 is connected between the third power line PL3 and a sixth node n6. The seventh switch element T7 is turned on according to the gate on voltage VGL of the second scan signal SCAN2 and applies the initialization voltage Vini to the sixth node n6. The seventh switch element T7 includes a first electrode connected to the third power line PL3 to which the initialization voltage Vini is applied, a gate electrode to which the second scan signal SCAN2 is applied, and a second electrode connected to the sixth node n6.

The eighth switch element T8 is connected between the first power line PL1 and the third node n3. The eighth switch element T8 is turned on according to a gate on voltage VGL of a light emission control signal EM and connects the first power line PL1 and the third node n3. The eighth switch element T8 includes a first electrode connected to the first power line PL1, a gate electrode to which the light emission control signal EM is applied, and a second electrode connected to the third node n3.

The ninth switch element T9 is connected between the first power line PL1 and a second node n2. The ninth switch element T9 is turned on the gate on voltage VGL of the light emission control signal EM and applies the pixel driving voltage VDD to the second node n2. The ninth switch element T9 includes a first electrode connected to the first power line PL1, a gate electrode to which the light emission control signal EM is applied, and a second electrode connected to the second node n2.

The tenth switch element T10 is connected between the fifth node n5 and the sixth node n6. The tenth switch element T10 is turned on according to the gate on voltage VGL of the light emission control signal EM and connects the fifth node n5 and the sixth node n6. The tenth switch element T10 includes a first electrode connected to the fifth node n5, a gate electrode to which the light emission control signal EM is applied, and a second electrode connected to the sixth node n6.

The first capacitor Cst is connected between the second node n2 and the fourth node n4. The second capacitor Csel is connected between a seventh node n7 and a fifth power line PL5 to which a common voltage is applied.

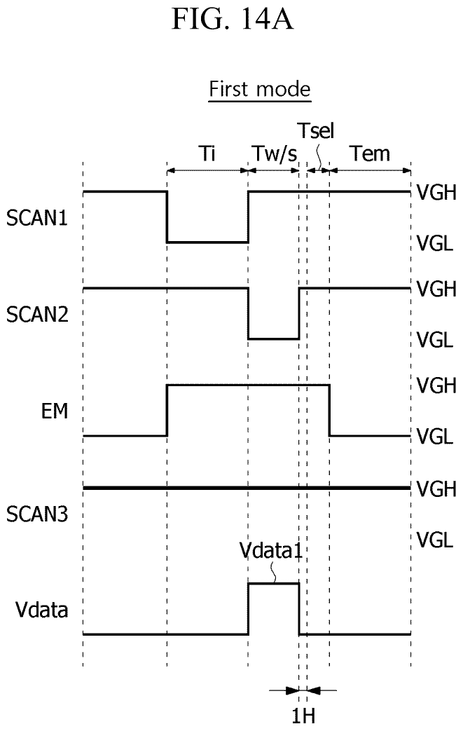

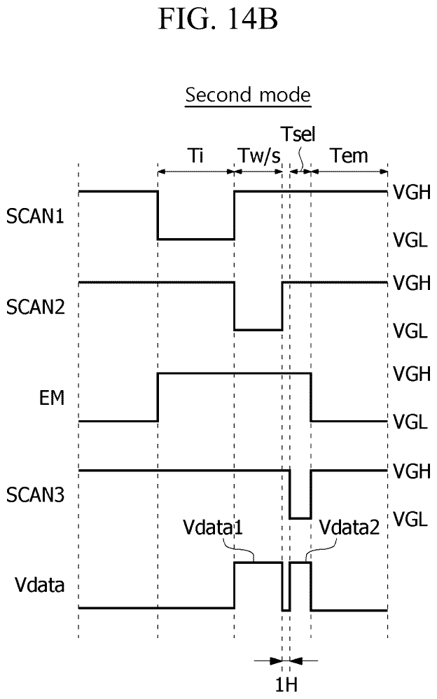

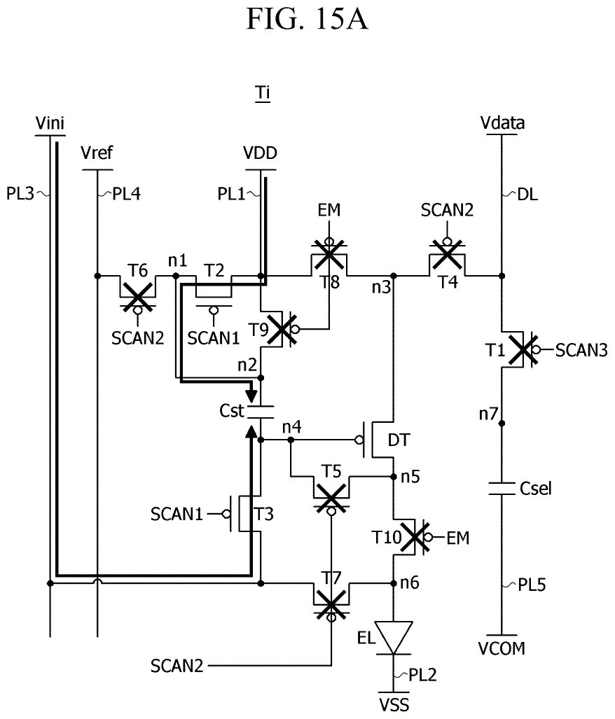

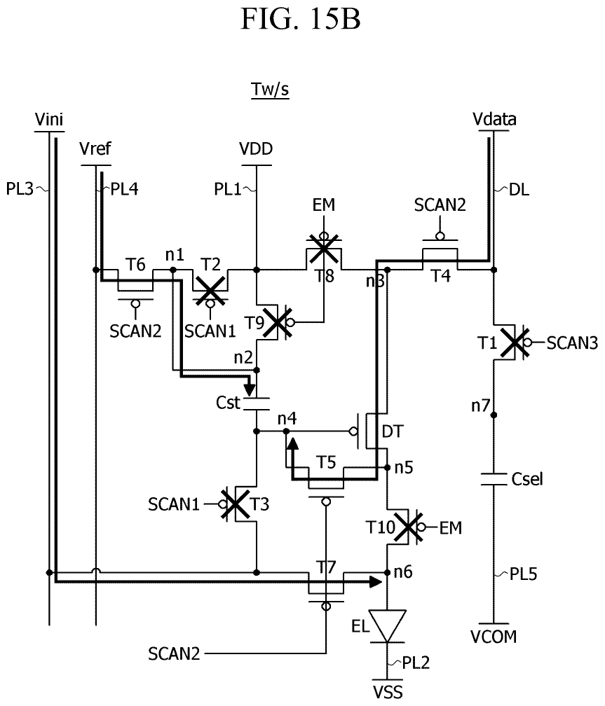

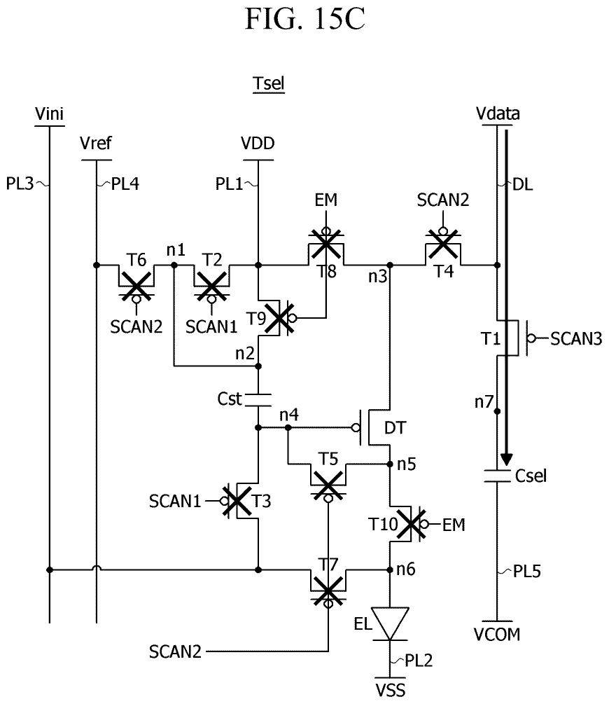

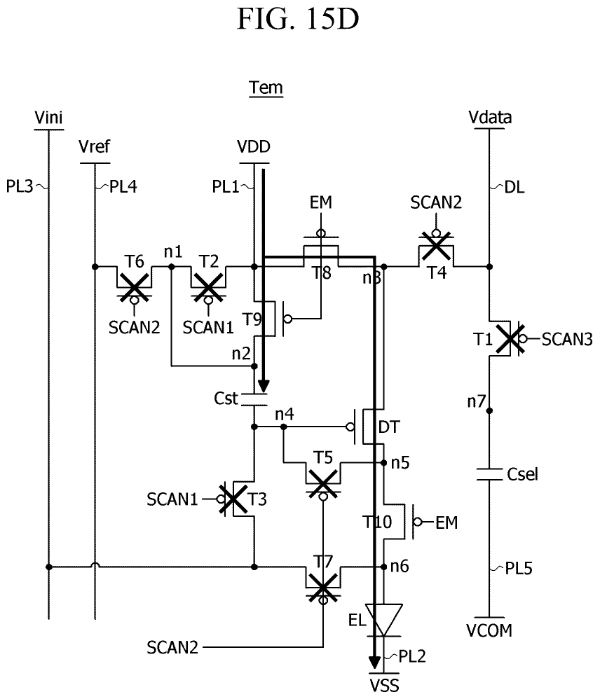

FIGS. 14A and 14B are diagrams illustrating mode-specific driving waveforms of the pixel circuit illustrated in FIG. 13 and FIGS. 15A to 15D are diagrams illustrating an operation principle of the pixel circuit according to FIG. 14B.

Referring to FIGS. 14A and 14B, the pixel circuit is driven in an order of the initialization period Ti, the data writing and sensing period Tw/s, the selection period Tsel, and the light emission period Tem in the first mode and the second mode.

Referring to FIG. 15A, during the initialization period Ti, the first switch element T1 and the fourth to tenth switch elements T4 to T10 are turned off, and the second and third switch elements T2 to T3 are turned on. Then, the pixel driving voltage is applied to the first node n1, and the initialization voltage is applied to the second node n2.

Referring to FIG. 15B, during the data writing and sensing period Tw/s, the first to third switch elements T1 to T3 and the eighth to tenth switch elements T8 to T10 are turned off, and the fourth to seventh switch elements T4 to T7 are turned on. Then, the first data voltage Vdata1 is applied to the driving element. Accordingly, the threshold voltage Vth of the driving element is sensed, and as a result, a voltage of the second node n2 becomes Vdata1+Vth. Further, the reference voltage Vref is applied to the first node n1, and the initialization voltage Vref is applied to the fifth node n5.

Referring to FIG. 15C, during the selection period Tsel, in the first mode, the first to tenth switch elements T1 to T10 are turned off, and in the second mode, the second to tenth switch elements T2 to T10 are turned off and the first switch element T1 is turned on. Then, the second data voltage Vdata2 is applied to the sixth node n6. As a result, the voltage of the sixth node n6 becomes “Vdata2”.

The data writing and sensing period Tw/s and the selection period Tsel are sections where different data voltages are applied. For this reason, to vary the data voltage, the selection period Tsel may start after at least 1 H from when the data writing and sensing period Tw/s ends.

Referring to FIG. 15D, during the light emission period Tem, the first to seventh switch elements T1 to T7 are turned off, and the eighth to tenth switch elements T8 to T10 are turned on. Then, the current generated according to the gate-source voltage of the driving element DT is supplied to the light-emitting element EL and light is emitted from the light-emitting element EL. As a result, the voltage of the first node n1 becomes “VDD”, and the voltage of the second node n2 becomes “VDD−Vref+Vdata+Vth”.

During the light emission period Tem, in the first mode, since the second data voltage Vdata2 is not applied to the second capacitor Csel, the light viewing angle is maintained wide. In the second mode, the light viewing angle is narrowed due to the second data voltage Vdata2 and the common voltage VCOM applied to the second capacitor Csel.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

What is claimed is:

1. A pixel circuit, comprising:
a light-emitting element;
a driving element configured to drive the light-emitting element;
a compensation circuit including a first capacitor, the first capacitor including a first electrode to which a first data voltage is applied via a data line and a second electrode connected to a gate electrode of the driving element;
a first switch element to which a predetermined second data voltage is supplied via the data line; and
a second capacitor including a first electrode connected to a second electrode of the first switch element and a second electrode connected to a power line to which a common voltage is applied.

2. The pixel circuit according to claim 1, wherein the light-emitting element is covered with a liquid crystal lens layer and is configured to emit light at a first viewing angle in a first mode and emit light at a second viewing angle narrower than the first viewing angle in a second mode according to whether the predetermined second data voltage is supplied.

3. The pixel circuit according to claim 2, wherein the first switch element is turned off in the first mode and is turned on in the second mode.

4. The pixel circuit according to claim 2, wherein the first switch element includes a first electrode connected to the data line, a gate electrode to which a gate signal is applied, and the second electrode connected to the first electrode of the second capacitor.

5. The pixel circuit according to claim 4, wherein:
the driving element includes a first electrode connected to a power line to which a pixel driving voltage is applied, the gate electrode connected to a second node, and a second electrode connected to a third node; and
the first capacitor is connected between a first node and the second node, and
wherein the compensation circuit includes:
a second switch element including a first electrode connected to the data line, a gate electrode to which a first scan signal is applied, and a second electrode connected to the first node;
a third switch element including a first electrode connected to the second node, a gate electrode to which a second scan signal is applied, and a second electrode connected to the third node;
a fourth switch element including a first electrode connected to the first node, a gate electrode to which a light emission control signal is applied, and a second electrode connected to a power line to which a reference voltage is applied;
a fifth switch element including a first electrode connected to the third node, a gate electrode to which the light emission control signal is applied, and a second electrode connected to a fourth node; and
a sixth switch element including a first electrode connected to the power line to which the reference voltage is applied, a gate electrode to which the second scan signal is applied, and a second electrode connected to the fourth node.

6. The pixel circuit according to claim 5, wherein:
the pixel circuit is driven in an order of an initialization step, a data writing and sensing step, a selection step, and a light emission step;
in the data writing and sensing step, the second switch element, the third switch element, and the sixth switch element are turned on, and the first data voltage is applied to the first electrode of the first capacitor; and
in the selection step after the data writing and sensing step, the first switch element is turned on, and the predetermined second data voltage is applied to the first electrode of the second capacitor.

7. The pixel circuit according to claim 6, wherein the selection step is driven when a predetermined time elapses after the data writing and sensing step ends.

8. The pixel circuit according to claim 4, wherein:
the driving element includes a first electrode connected to a third node, the gate electrode connected to a fourth node, and a second electrode connected to a fifth node, and
the first capacitor is connected between a second node and the fourth node, and
wherein the compensation circuit includes:
a second switch element including a first electrode connected to a first node, a gate electrode to which a first scan signal is applied, and a second electrode connected to a power line to which a pixel driving voltage is applied;
a third switch element including a first electrode connected to the fourth node, a gate electrode to which the first scan signal is applied, an a second electrode connected to a power line to which an initialization voltage is applied;
a fourth switch element including a first electrode connected to the third node, a gate electrode to which a second scan signal is applied, and a second electrode connected to the data line;
a fifth switch element including a first electrode connected to the fourth node, a gate electrode to which the second scan signal is applied, and a second electrode connected to the fifth node;
a sixth switch element including a first electrode connected to a power line to which a reference voltage is applied, a gate electrode applied to the second scan signal, and a second electrode connected to the first node;
a seventh switch element including a first electrode connected to the power line to which the initialization voltage is applied, a gate electrode to which the second scan signal is applied, and a second electrode connected to an anode electrode of the light-emitting element;
an eighth switch element including a first electrode connected to the power line to which the pixel driving voltage is applied, a gate electrode to which a light emission control signal is applied, and a second electrode connected to the third node;
a ninth switch element including a first electrode connected to the power line to which the pixel driving voltage is applied, a gate electrode to which the light emission control signal is applied, and a second electrode connected to the second node; and
a tenth switch element including a first electrode connected to the fifth node, a gate electrode to which the light emission control signal is applied, and a second electrode connected to the anode electrode of the light-emitting element.

9. A display device, comprising:
a display panel including a display area in which a plurality of sub-pixels are provided,
wherein the display panel includes:
a substrate;
a circuit layer provided above the substrate;
a light-emitting element layer provided above the circuit layer;
an encapsulation layer provided above the light-emitting element layer; and
a liquid crystal lens layer including a first electrode including multiple electrode patterns spaced apart from each other above the encapsulation layer, a liquid crystal layer that covers the first electrode, and a second electrode provided above the liquid crystal layer, and
wherein a predetermined data voltage is applied to each of the multiple electrode patterns provided in the first electrode, and a predetermined common voltage is applied to the second electrode.

10. The display device according to claim 9, wherein the plurality of sub-pixels include a first sub-pixel, a second sub-pixel and a third sub-pixel, and
wherein the multiple electrode patterns include:
a first electrode pattern to which a data voltage applied to the first sub-pixel is applied;
a second electrode pattern to which a data voltage that is applied to the second sub-pixel is applied; and
a third electrode pattern to which a data voltage that is applied to the third sub-pixel is applied.

11. The display device according to claim 10, wherein the multiple electrode patterns have a circular shape or a quadrangular shape.

12. The display device according to claim 11, wherein:
the second electrode pattern is formed inward with respect to the first electrode pattern and spaced apart from the first electrode pattern; and
the third electrode pattern is provided inward with respect to the second electrode pattern and spaced apart from the second electrode pattern.

13. The display device according to claim 12, wherein a data voltage that is applied to the second electrode pattern is higher than a data voltage that is applied to the first electrode pattern and lower than a data voltage that is applied to the third electrode pattern.

14. The display device according to claim 10, wherein the multiple electrode patterns are formed for each sub-pixel or for each predetermined area of multiple sub-pixels.

15. The display device according to claim 14, wherein the liquid crystal lens layer is formed for each sub-pixel or for each predetermined area of multiple sub-pixels.

16. The display device according to claim 9, wherein each of the plurality of sub-pixels includes:
a light-emitting element;
a driving element configured to drive the light-emitting element;
a compensation circuit including a first capacitor, the first capacitor including a first electrode to which a first data voltage is applied via a data line and a second electrode connected to a gate electrode of the driving element;
a first switch element to which a predetermined second data voltage is supplied via the data line; and
a second capacitor including a first electrode connected to a second electrode of the first switch element and a second electrode connected to a power line to which a common voltage is applied.

17. The display device according to claim 16, wherein the light-emitting element is covered with a liquid crystal lens and is configured to emit light at a first viewing angle in a first mode and emit light at a second viewing angle narrower than the first viewing angle in a second mode according to whether the predetermined second data voltage is supplied.

18. The display device according to claim 17, wherein the first switch element is turned off in the first mode and is turned on in the second mode.

19. The display device according to claim 18, wherein the first switch element includes a first electrode connected to the data line, a gate electrode to which a gate signal is applied, and the second electrode connected to a first electrode of the second capacitor.
